(19) United States
(12) Patent Application Publication
(10) Pub. No.: US 2011/0198570 A1
(43) Pub. Date: Aug. 18, 2011

(54) SELF ASSEMBLED NANO DOTS (SAND) AND NON-SELF ASSEMBLED NANO-DOTS (NSAND) DEVICE STRUCTURES AND FABRICATION METHODS THEREOF TO CREATE SPACERS FOR ENERGY TRANSFER

(75) Inventor: Rama Venkatasubramanian, Cary, NC (US)

(73) Assignee: Research Triangle Institute, Research Triangle Park, NC (US)

(21) Appl. No.: 12/893,647

(22) Filed: Sep. 29, 2010

Related U.S. Application Data
(60) Provisional application No. 61/304,382, filed on Feb. 12, 2010.

(51) Int. Cl. H01L 29/66; H01L 23/34; H01L 35/00; F28F 7/00

(52) U.S. Cl. 257/30; 257/712; 136/213; 257/10; 165/185; 257/E29.168; 257/E23.08

(57) ABSTRACT

A structure and method for transferring electronic charge or heat or light between substrates. The structure includes first and second substrates separated from one another and a plurality of localized spacers connecting the first and second substrates together. At least one of the localized spacers having a lateral dimension less than 350 nm. A sub-micron separation distance between the first and second substrates is configured to provide carrier tunneling or to provide heat transfer or light transfer between the first and second substrates. The method provides charge carriers or heat or light to a first substrate. The first substrate is separated from a second substrate by at least one localized spacer having a lateral dimension less than 350 nm and tunnels the charge carriers or couples the heat or couples light from the first substrate to the second substrate across a sub-micron gap between the first and second substrates formed by the at least one localized spacer.

### CROSS REFERENCE TO RELATED APPLICATIONS

This application is related to and claims priority under 35 U.S.C. 119(e) to U.S. provisional patent application 61/304,382, filed Feb. 12, 2010, the entire contents of which are hereby incorporated by reference.

### BACKGROUND OF THE INVENTION

1. Field of the Invention

This invention relates to the field of substrate device integration for electronic energy transfer, optical energy transfer and thermal energy transfer from one substrate to another.

2. Description of the Related Art

In the past decade, nanometer scale particles or nano-dots or quantum-dots that self-assembled on a surface have been studied for a variety of applications, particularly in quantum electronics or optoelectronics. For example, it is known that Ge nano-dots form naturally on Si (100) surfaces during deposition of Ge thereon in order to reduce the build-up of elastic strain and minimize the energy. The effect is known in the art by the Stromski-Krastanov (SK) growth mode.

Ge nano-dots of height 4 to 15 nm with widths or diameter of 20-30 nm have been grown. Ge nano-dots in the range of 4 nm size have been grown on SiₓGe₁₋ₓ oxide films. Ge nano-dots on Si have also been demonstrated using an anodic alumina membrane mask as well as through deposition of Ge with latex nano-spheres as a mask. Ge nano-dots in the height range of 8 nm have been produced using an anodic alumina membrane. Nano-sphere lithography has produced Ge dots in the 30 nm size range. These approaches, while are not as attractive as self-assembled approaches, can lead to better control of spatial and size distribution of nano-dots than the self-assembled approaches. Thus, technology has come to exist recently for the formation of controlled spatially small (˜50 nm in height or less) nano-dots of Ge on Si.

Nano-dots in other material systems have also been demonstrated. For example, self-organized iron silicide nano-dots have been demonstrated on SiₓGe₁₋ₓ or strained Si. Recently, silicide nano-dots as small as 3 nm, in height or diameter, have been grown on oxidized Si. GaN, a high-band-gap material, has been grown as 2-3 nm dots on Al_{0.15}Ga_{0.85}N using Si as anti-surfactant. Similarly, InAs nano-dots have been grown on GaAs substrates.

Despite the development of materials growth and understanding of nano-dot formation, the application of nano-dots has been directed primarily to electronic and optoelectronic devices where the nano-dots are the active elements.

### SUMMARY OF THE INVENTION

In one embodiment of the invention, there is provided a device structure for electronic transfer between substrates. The device structure includes first and second substrates separated from one another, a plurality of localized spacers connecting the first and second substrates together and at least one of the localized spacers having a lateral dimension less than 350 nm. A sub-micron separation distance between the first and second substrates is configured to provide tunneling of carriers between the first and second substrates.

In one embodiment of the invention, there is provided a device structure for photonic transfer between substrates. The device structure includes first and second substrates separated from one another, a plurality of localized spacers connecting the first and second substrates together and at least one of the localized spacers having a lateral dimension less than 350 nm. A sub-micron separation distance between the first and second substrates is configured to provide tunneling of photons between the first and second substrates.

In one embodiment of the invention, there is provided a device structure for heat transfer between substrates. The device structure includes first and second substrates separated from one another, a plurality of localized spacers connecting the first and second substrates together and at least one of the localized spacers having a lateral dimension less than 350 nm. A sub-micron separation distance between the first and second substrates is configured to provide heat transfer between the first and second substrates.

In one embodiment of the invention, there is provided a substrate-to-substrate coupling structure. The coupling structure includes a first substrate and a second substrate separated from the first substrate by a sub-micron distance configured to couple electrical carriers or heat between one of the first and second substrates to the other. The coupling structure includes a plurality of self-assembled nanodots connecting the first and second substrates together. The self-assembled nanodots are formed by growth of a material of the nanodot on the first substrate.

In one embodiment of the invention, there is provided a method for transferring electronic charge between substrates including (1) providing charge carriers to a first substrate, the first substrate separated from a second substrate by at least one localized spacer having a lateral dimension less than 350 nm, and (2) tunneling the charge carriers from the first substrate to the second substrate across a sub-micron gap between the first and second substrates formed by the at least one localized spacer.

In one embodiment of the invention, there is provided a method for transferring heat between substrates including (1) providing heat to a first substrate, the first substrate separated from a second substrate by at least one localized spacer having a lateral dimension less than 350 nm, and 2) coupling the heat from the first substrate to the second substrate across a sub-micron gap of between the first and second substrates formed by the at least one localized spacer.

It is to be understood that both the foregoing general description of the invention and the following detailed description are exemplary, but are not restrictive of the invention.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a schematic depicting a device structure according to one embodiment of the invention utilizing nano-dots to form a gap separating two substrates from one another and suitable for electronic tunneling between the substrates;

FIG. 2 is a schematic similar to FIG. 2 depicting a device structure according to one embodiment of the invention utilizing Ge nano-dots to form a gap separating a p-type Si substrate from a n-type Si substrate;

FIG. 3 is a SEM micrograph showing a top view of a Si substrate having a SAND configuration;]

FIG. 4 is a SEM micrograph showing a top view of a Si substrate having a NSAND configuration;

FIG. 5 is a schematic illustration depicting a device structure according to one embodiment of the invention utilizing nano-dots to form a gap separating two substrates from one another in which the nanodots are joined to one of the substrate in an insulating region of that substrate;

FIG. 6 is a flow chart depicting a method for making some of the SAND and NSAND configurations of the invention;

FIG. 7 is a schematic illustration depicting a device structure according to one embodiment of the invention utilizing nano-dots to mechanically attach substrates of disparate thermal expansion properties;

FIG. 8 is a schematic illustration depicting a thermo-tunneling device of the invention for refrigeration and energy conversion;

FIG. 9 is a schematic illustration depicting a thermo photovoltaic device of the invention;

FIG. 10 is a schematic illustration depicting a vacuum thermionic emitter device of the invention;

FIG. 11A is a schematic illustration depicting a photon coupler device of the invention; and

FIG. 11B is a schematic illustration depicting another photon coupler device of the invention.

### DETAILED DESCRIPTION OF THE PREFERRED EMBODIMENTS

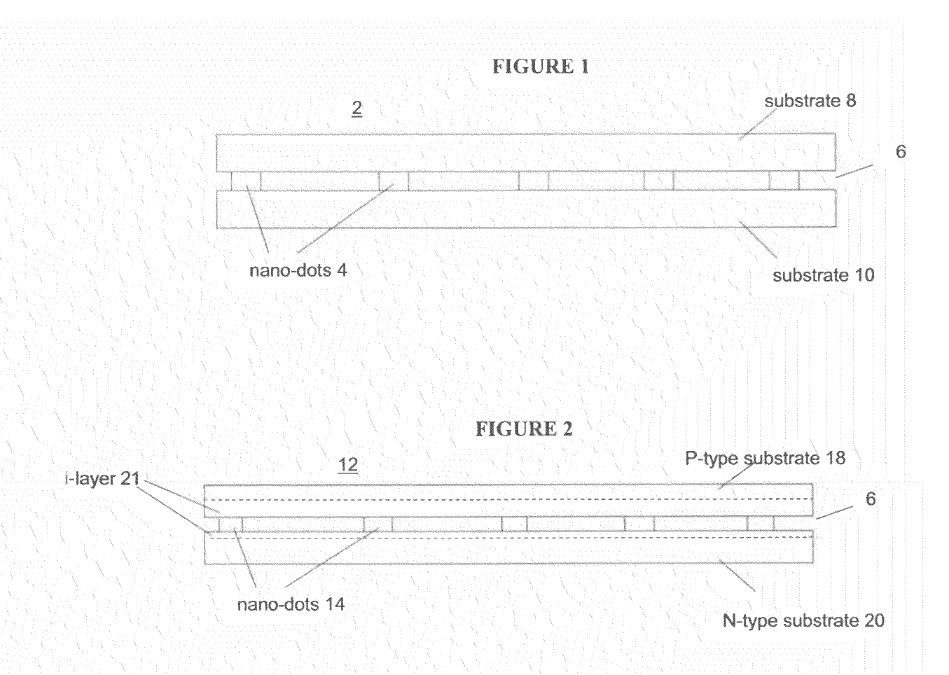

In one embodiment of the invention, self-assembled and/or non-self-assembled nano-dots are provided as “localized spacers” to achieve a nano-gap separation for a variety of electronic and energy conversion applications. Referring now to the drawings, wherein like reference numerals designate identical or corresponding parts throughout the several views, in FIG. 1, FIG. 1 depicts a device structure 2 according to one embodiment of the invention utilizing nano-dots 4 to form a gap 6 separating two substrates 8, 10 from one another. The gap 6 (determined by the height of the nano-dots) is in a range from 2-100 nm to provide carrier tunneling (e.g., with electrons for negative charge carriers or holes for positive charge carriers) between the substrates in one embodiment of the invention and is in a range from 2-1000 nm to promote infrared coupling and/or heat transfer between the substrates in another embodiment of the invention. In one more specific embodiment for carrier tunneling, a gap separation in the range of 1 to 50 nm is used. In one more specific embodiment for IR photon tunneling, a gap separation in the range of 1 to 1000 nm is used. Thus, in general, the gap separation can be in a range from 1 to 1000 nm, 1 to 500 nm, 1 to 300 nm, 1 to 200 nm, 1 to 100 nm, 1 to 50 nm, 1 to 20 nm, or 1 to 10 nm.

In one embodiment of the invention, the nano-dots 4 have a lateral dimension that is less than 1000 nm. In another embodiment of the invention, the nano-dots 4 have a lateral dimension that is less than 100 nm. In another embodiment of the invention, the nano-dots 4 have a lateral dimension that is less than 10 nm. In another embodiment of the invention, the nano-dots 4 have a lateral dimension that is less than 5 nm. Thus, in general, the lateral dimension can be in a range from 1 to 1000 nm, 1 to 500 nm, 1 to 300 nm, 1 to 200 nm, 1 to 100 nm, 1 to 50 nm, 1 to 20 nm, or 1 to 10 nm.

In one embodiment of the invention, the nano-dots 4 can be formed from intrinsically high band-gap materials (e.g., as in GaN nano-dots) or through an increase of an effective band-gap from quantum confinement (e.g., as in Ge nano-dots). Accordingly, the nanodots in one embodiment can be a relatively poor electrical conductor as compared to macroscopic Ge. In one embodiment of the invention, the nano-dots 4 can be formed from III-V materials such as InAs or InGasAs formed on GaAs. U.S. Pat. Appl. Publ. No. 2007/0215857 (the contents of which are incorporated herein in its entirety) describes methods for forming InGaAs nanodots. In addition, materials such as Ge, Si, PbTe, Bi₂Te₃ in small dimensions are known to have low thermal conductivity, especially in the length scales 1 to 10 nm. Thus, in one embodiment of the invention, a plurality of self-assembled and non-self-assembled nano-dots can form thermal and electrically insulating spacers for a variety of device applications discussed below. These self-assembled and non-self-assembled nano-dots form a gap separating two substrates with the gap being small enough to promote electron tunneling, hole tunneling, infrared coupling, and/or convective heat transfer across the gap without imposing on the respective substrates stress related defects associated normally with the joining integrally or by bonding two substrates or substrate materials together.

The nano-dots 4 (formed by self-assembly or surfactant-assisted or through masks on a variety of substrates) can be preformed as Ge nanodots on silicon and subsequently trimmed by selective reactive ion etching to reduce the height of the Ge nanodots. In one embodiment, lithography is used to remove a percentage of the nano-dots on the surface to create a hybrid structure where self-assembly and patterning are used to form the localized spacers of the invention. In this embodiment, a set of nanodots remain on the substrate after etch removal of selected ones of the nanodots initially formed on the substrate.

In one embodiment, the nano-dots 4 can have a height for example from 1 nm to 20 nm in one embodiment. In one embodiment, the nano-dots 4 can have a width in a range of 20-30 nm. These dimensions are considered illustrative and not limiting the invention. In one embodiment, nanodots of Si (or Ge) can be formed by epitaxially overgrowing a thin oxide (e.g., 1-2 nm thick) and then using lithographic techniques to remove the region of Si that was not the overgrown part. U.S. Pat. No. 6,730,531 (the contents of which are incorporated herein in its entirety) describes such a method for the overgrowth of Si on thicker oxides than those described above.

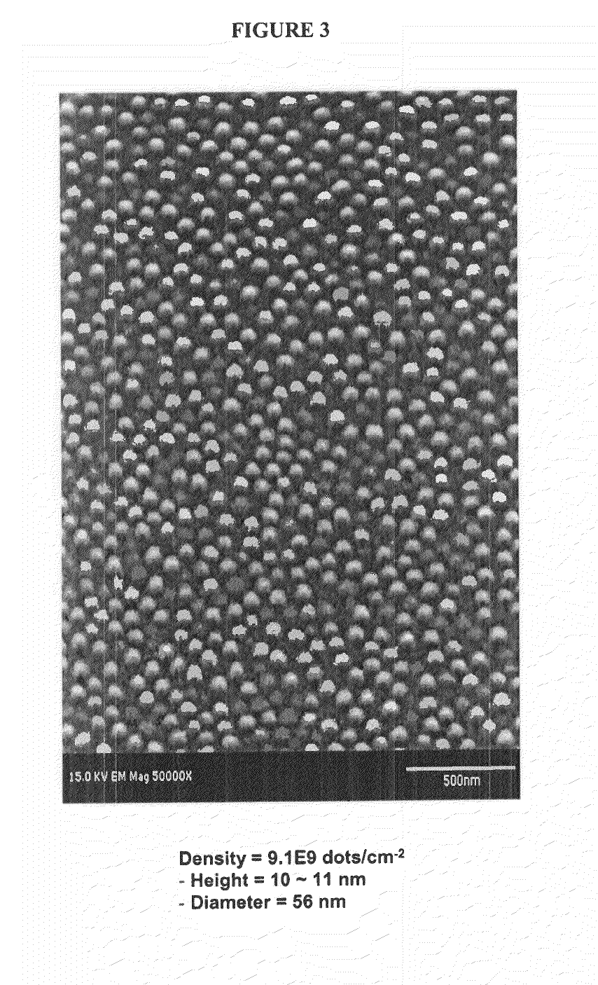

In one embodiment of the invention, the substrates 8 and 10 in FIG. 1 are p-type Si and n-type Si substrates, respectively. FIG. 2 depicts a device structure 12 according to one embodiment of the invention utilizing Ge nano-dots 14 to form a gap 16 separating two substrates 18, 20 from one another. In this embodiment, a PN junction is formed in the substrates 18 and 20 by for example electron tunneling from the p-type Si 18 substrate into and depleting a region of the p-type and n-type substrates 18, 20 and forming an intrinsic layer 21 in a p-i-n structure. Similar to conventional PN junction formation, tunneling of electrons from the n-type to the p-type substrate continues until a self bias opposes further electron tunneling.

The structure shown in FIG. 2 can have a number of applications including for example photovoltaic conversion. In traditional single crystal or polycrystalline photovoltaic conversion, the conversion efficiency is limited by the dark current which flows across the PN junction. In traditional polycrystalline Si solar cells, the polycrystalline boundaries increase the dark current and reduce the photovoltaic efficiency. The barrier to dark current flow is typically limited to the electronic band gap of the silicon of 1.2 eV. However, in the configuration shown in FIG. 2, the nano-gap presents an additional barrier to reverse current flow, and thereby would be expected to improve the photovoltaic conversion efficiency.

In this application, the Ge nano-dots (if of a macroscopic size) would electrically “short” charge across the gap. Yet, as noted above, the quantum confinement effects make Ge nano-dots more electrically insulating than bulk macroscopic Ge. Furthermore, in one embodiment of the invention, the Ge nano-dots can be oxidized at temperatures below which the Si surfaces will oxidize, thereby making the Ge nano-dots even more insulating. In some cases, Ge can be replaced by higher bandgap materials such as GaAs, GaN or other spacer materials to reduce the dark current further. Such approaches to reducing dark current can be even more advantageous for organic photovoltaic junctions, where large leakage currents are a significant problem.

Moreover, the “shorting” effect can be controlled by reducing the density and placement of the nanodots. A reduced density reduces the number of places for one substrate to “short” to another. For example, in a self-assembled nanodot (SAND) configuration, the nano-dots 4 have a density of approximately 10¹⁰ cm⁻². In a non-self-assembled nanodot (NSAND) configuration, where the density of the nanodots has been reduced, the nano-dots 4 have a density of approximately 10⁸ cm⁻². Thus, lithographic patterning and etching can be used to reduce the density of nano-dots 4 and thereby control of the spatial and/or size distribution of nano-dots. In one embodiment of the invention, the nano-dot density can be reduced to 10⁴ cm⁻².

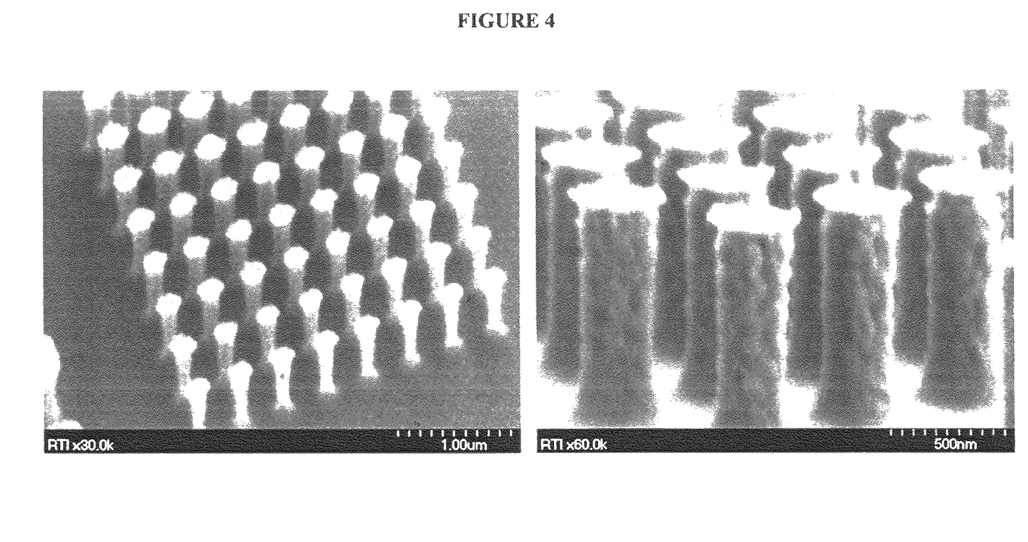

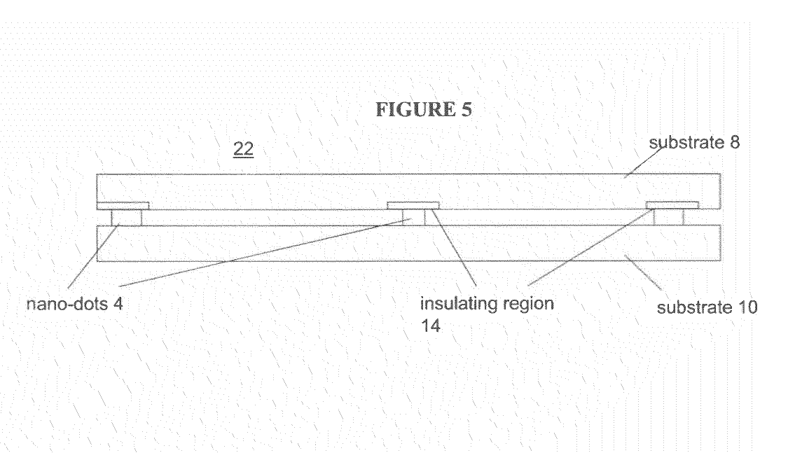

FIG. 3 is a SEM micrograph showing a top view of a Si substrate having a SAND configuration of Ge nano-dots on Si substrate. FIG. 4 is a SEM micrograph showing a top view of a Si substrate having NSAND configurations. The SEM micrograph of FIG. 4 shows NSAND Si nanostructures on top of a Si substrate that have been created by electron-beam lithography patterning and highly anisotropic Si etching. Here anisotropic etching leads to vertical etching of Si without undercutting. The perspective of FIG. 4 makes the appearance of the nanodots to appear almost as nano-rods. Basically, the invention encompasses either nano-dot or nano-rod structures which are useable as structures to separate adjacent substrates. Here, in the NSAND configuration, the separation distance between two substrates and the size and density of the localized spacers are set by the electron-beam lithography or similar methods such as extreme-UV lithography and the degree of etching, respectively.

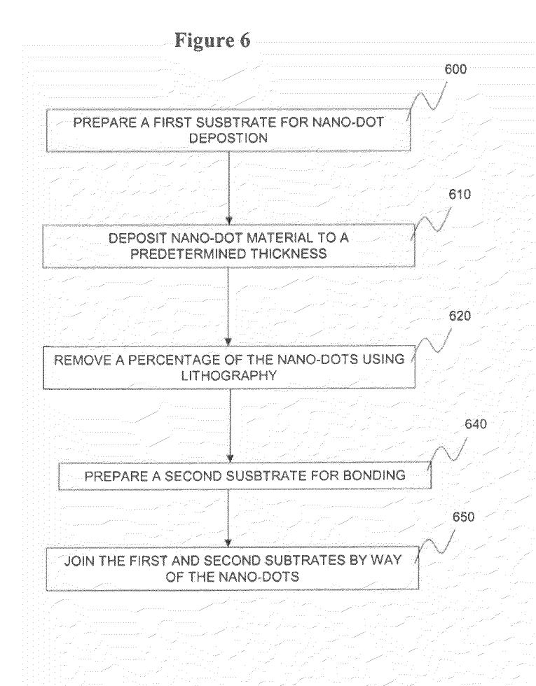

FIG. 5 is a schematic illustration depicting a device structure 22 according to one embodiment of the invention utilizing nano-dots 4 to form a gap separating two substrates 8, 10 from one another in which the nanodots 4 are joined to one of the substrates at insulating regions 14 of that substrate. The use of insulating regions depends on the application of the device structure. In the photovoltaic conversion application described above the insulating regions would be advantageous, although in some photovoltaic applications the depletion region itself formed in the p-type and n-type substrates may be sufficient to limit the dark current to acceptable values without use of the insulating regions 14. Further, the removal of a percentage of the nano-dots is sufficient in one embodiment to limit the dark current to acceptable values without use of the insulating regions 14.

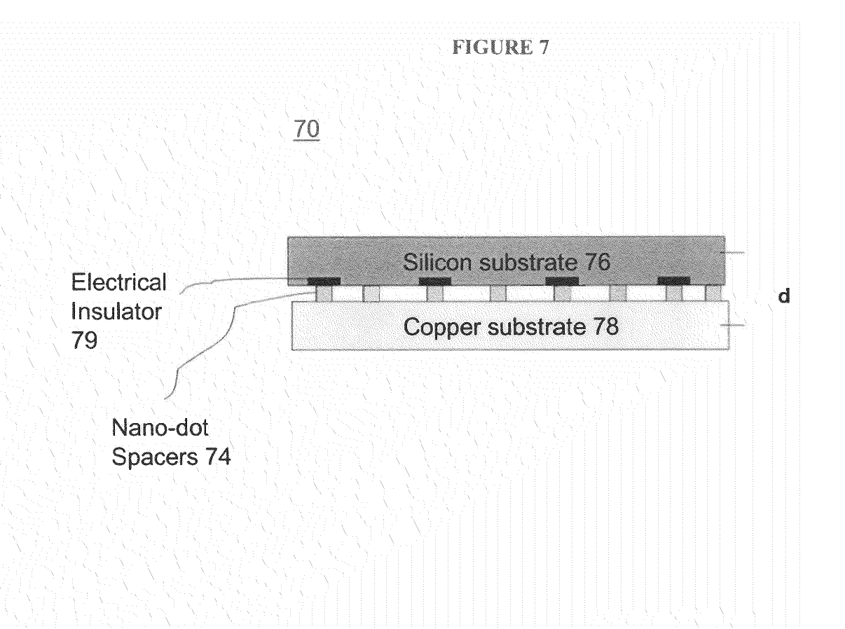

FIG. 6 is a flow chart depicting a method for making the SAND and NSAND configurations of FIG. 1 and FIG. 5. While specifically illustrated with respect to Si substrates and Ge nano-dots, the techniques apply to other material system combinations. At 600, a first substrate (e.g., Si substrate 8) is prepared for nano-dot material deposition (e.g., Ge nano-dot deposition). Techniques for cleaning the surface of the Si substrate prior to Ge deposition are known and include for example a RCA treatment and an anneal in a reducing or vacuum environment to remove any surface oxides or surface terminations. Planarization steps such chemical mechanical polishing may also be used if needed to planarize the first substrate before nano-dot material deposition.

At 610, the nano-dot material is deposited to a predetermined thickness one or the other of the substrates 8, 10. Owing to stress between the Ge lattice constant and the Si lattice constant, the Ge deposits in “islands” forming Ge nano-dots on the Si surface (i.e., the Ge does not conformally deposit on the Si surface but preferentially coalesces on itself). Other materials systems as described above in the background section can be used in various embodiments of the invention to form nano-dots 4 on substrate 8 or substrate 10.

At 630, optionally, lithographic patterning using conventional masking techniques and materials can be used to remove a percentage of the nano-dots. The percentage of nano-dots removed will depend on the application. In some applications, over 99.999% of the nano-dots are removed to reduce a pathway for inadvertent conduction (heat or thermal) through the gap between the first and second substrates. In other applications, only 10% or fewer of the nano-dots are removed, for example in heat transfer applications where any pathway for heat from the first substrate to be dissipated to the second substrate is beneficial.

At 640, a second substrate is prepared for subsequent bonding to the first substrate by way of connection to the nano-dots. If the second substrate is of the same material as the first substrate, the surface of the second substrate will typically be cleaned using at least some or similar procedures as with the first substrate. If the second substrate is not of the same material as the first substrate, the surface of the second substrate will typically be cleaned using procedures appropriate for the second substrate.

At 640, the second substrate after or before the cleaning may have selected regions of the substrate oxidized or nitrided. For example, a mask material such as for example silicon oxide, silicon nitride, or a photoresist material is used to cover the portion of the second substrate. A low energy oxygen (or nitrogen) ion bombardment process or a plasma oxidation (or nitrification) assisted process, for example, is then used to form an oxide (or nitride) in a nearby surface region of the second substrate exposed to the oxidation process. The mask material is then removed.

At 650, the second substrate is joined to the first substrate by way of the nano-dots. At 650, the nano-dots become bonded to the second substrate using known bonding techniques such as for example solder-eutectic bonding, ultrasonic bonding, hydrogen bonding, van der Waal forces assisted bonding etc. The solder or eutectic metal could be applied as part of the masking process to create NSAND structures, as shown in FIG. 4, or by evaporating nanoscale metal films by techniques such as e-beam evaporation and onto the SAND structures. Note in the latter approach, the metal on top of the SAND will be used for bonding to the mating surface while the metal on other areas are left unutilized or etched away later.

In the processes described above, a predetermined array or packing fraction of nano-dots, predetermined height of nano-dots, predetermined shape of nano-dots, predetermined materials in nano-dots, and predetermined attachments between two surfaces (e.g., one with nano-dot spacers coated thereon and the other without) can be used to achieve predetermined gaps ranging from a nm to hundreds of nm.

In various embodiments of the invention, the SAND and NSAND nano-gaps are utilized between two surfaces of bulk materials forming tunneling junctions across the nano-gaps, thereby permitting unique combinations of materials electrically coupled across the gap by tunneling but structurally “isolated” and thereby avoiding traditional heterostructure problems such as stress and thermal mismatch, and the defects resulting therefrom. Such nano-gap heterostructures according to the invention have applications in areas such as for example refrigeration, energy conversion, thermal compliant interfaces, displays, proximity lithography, single junction on organic PV materials and multi-junction solar cells using free-space tunneling structures, electronics packaging and nano-electro-mechanical systems (to be discussed in more detail below).

In another embodiment of the invention, self-assembled nano-dots (SAND) and/or non-self-assembled nano-dots (NSAND) form spacers in an electrically “insulating” and thermally “insulating” structure. “Insulating” in this embodiment implies significantly reduced conduction of electricity and/or heat as compared to bulk macroscopic materials of the same material as the SAND and/or NSAND spacers. Accordingly, these spacers could be used in electronics packaging such as for example the joining “thermally” of a conductive Cu heat sink to a Si device chip. Typically, the thermal expansion differences between Si and Cu are so large that the direct attachment of even a few hundreds of microns of Cu to a bulk Si device chip induces catastrophic coefficient of thermal expansion CTE-difference induced damage to the Si device chip.

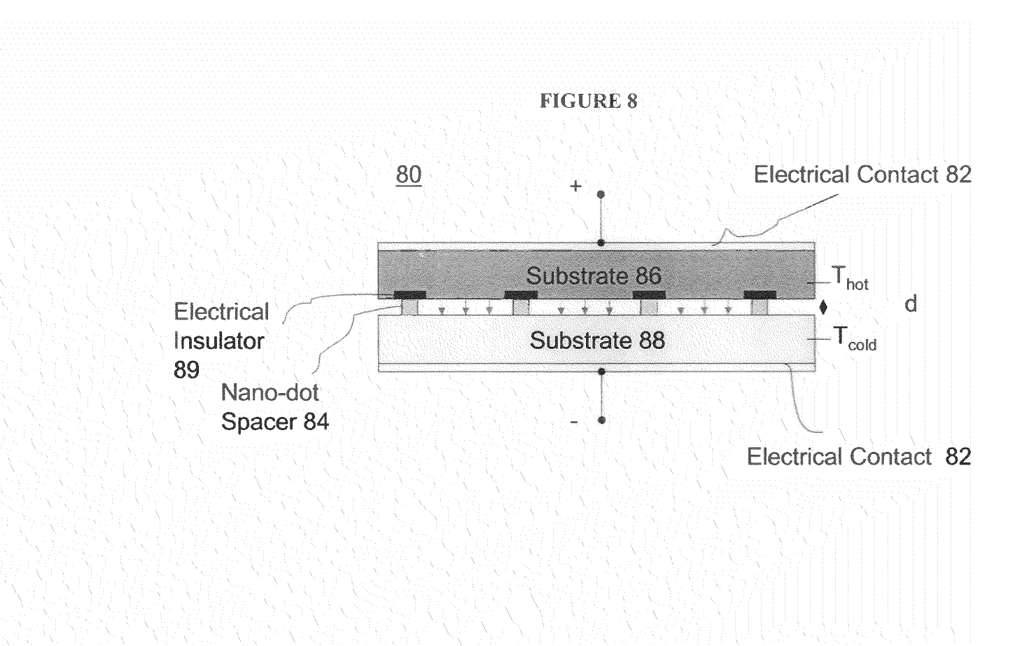

In one embodiment of the invention, nano-dots are used to “join” different substrates together that normally would not have been amenable to joining due to disparate thermal expansion differences. FIG. 7 shows an example of a bulk Si substrate 76 (e.g., including IC chips that can be contained in it) joined to a Cu substrate 78, e.g. serving as a heat sink. The engineered gap is formed by patterning localized spacers 74 (e.g., nano-dots) on the Cu substrate 78. Suitable nano-dots for this embodiment (and others) include Sn, In, InSn, AgSn, Bi, Sb, etc. These nano-dot materials would be used to form SAND or NSAND structures on Cu surface and at the same time form a low-temperature eutectic with Sn and Cu or some metal on Si and Cu. Alternatively, by patterning the above-noted Ge nano-dots on the Si device chip (e.g., on the Si device chip backside provided before the device IC or discrete device formation) and then binding the two substrates (i.e., the device chip and the Cu heat sink) together, a controlled gap is provided through which thermal transport can occur either by enhanced IR coupling or by increased thermal conduction across the gas in the nm-sized gap d. As shown in FIG. 7, some of the localized spacers 74 can be further electrically isolated. In one embodiment, all the spacers may be electrically insulating. In another embodiment, some of the localized spacers are electrically conductive and constitute a part of an electrical interconnect to and from the Si substrate 76. The nano-dots (due to their small size and/ore reduced density as in the NSAND configuration) are expected to be compliant, permitting expansions (or contractions) of the Cu material to be accommodated without transfer of catastrophic coefficient of thermal expansion (CTE) mismatch stresses to the Si device chips. The density of nano-spacers per unit area or the packing fraction of spacers can be chosen to be high enough to conduct the heat between Si and Cu but while minimizing the CTE mismatch issues.

In one embodiment of the invention, nano-dots are used to “join” different types of organic semiconductor materials. Direct formation of different types of organic materials historically has been frustrated due to the formation of defect states at the interface as these different materials are joined. In this embodiment, the SAND and NSAND configurations permit “bulk” type performance of the respective materials without the prolific formation of defect states at the interface of, for example, what would have been between a n-type organic material to a p-type organic material.

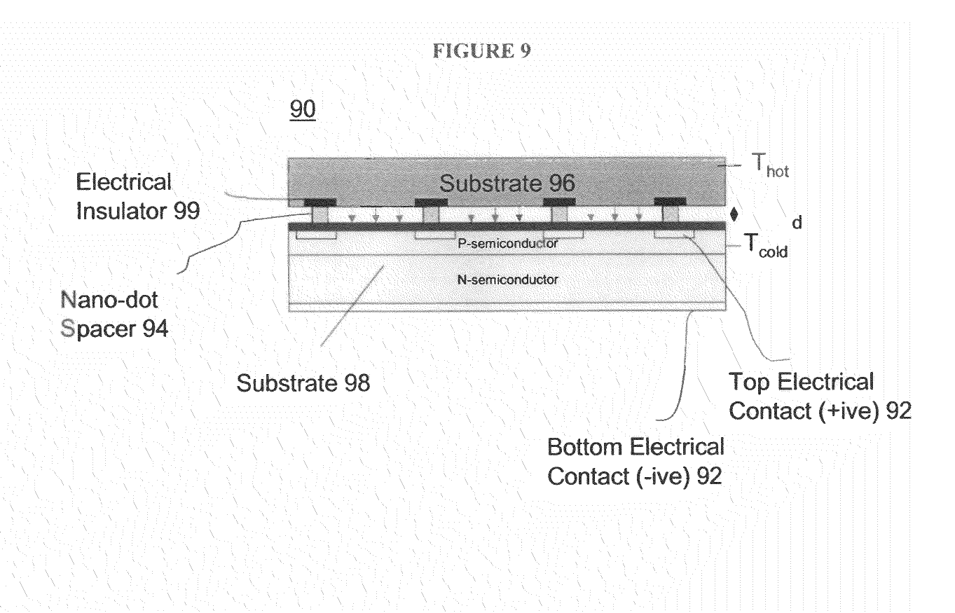

In one embodiment of the invention, self-assembled nano-dots (SAND) and/or non-self-assembled nano-dots (NSAND) form spacers in thermo-tunneling devices for refrigeration and energy conversion. FIG. 8 shows a thermo-tunneling device 80, according to one embodiment of the invention, which benefits from the localized spacers described herein (e.g., the SAND and NSAND spacers). In a thermo-tunneling device, according to one embodiment of the invention, nano-gaps in the range of 1 to 10 nm are utilized in thermo-tunneling refrigeration and power conversion devices of the invention. Electrons tunnel carrying the heat energy across the separation distance d, thereby creating an electric potential to drive an external electric load, while phonons or thermal waves are not able to tunnel. This effect leads to efficient heat-to-electric conversion using the thermo-tunneling effect.

In one embodiment of the invention, the electron wavelength (λₑ)>>d (the separation distance) and phonon wavelength (λₚₕ)<<d. As shown in the embodiment of FIG. 8, the thermo-tunneling device 80 has electrical contacts 82 to substrates 86 and 88 which are separated by localized spacers 84 shown illustratively in FIG. 8 as nano-dots. In one embodiment, an electrical insulator 89 is used to preventing “shorting” of the upper and lower substrates. In one embodiment, the upper and lower substrates are conducting semiconductor materials or metal substrates. In one embodiment, the upper substrate 86 receives a flux of tunneling electrons carrying heat from the lower substrate 88 (on the application of external voltage) to the substrate 86, and the lower substrate becomes colder, as in a refrigeration device. In another embodiment, the substrate 86 is exposed to a heat source. The tunneling of heat-energy-induced electrons from the upper substrate 86 to a heat-sink 88 produces a voltage difference between the upper and lower substrates. Here the two ends of the upper and lower substrates act as electrodes in a refrigeration or a power conversion device.

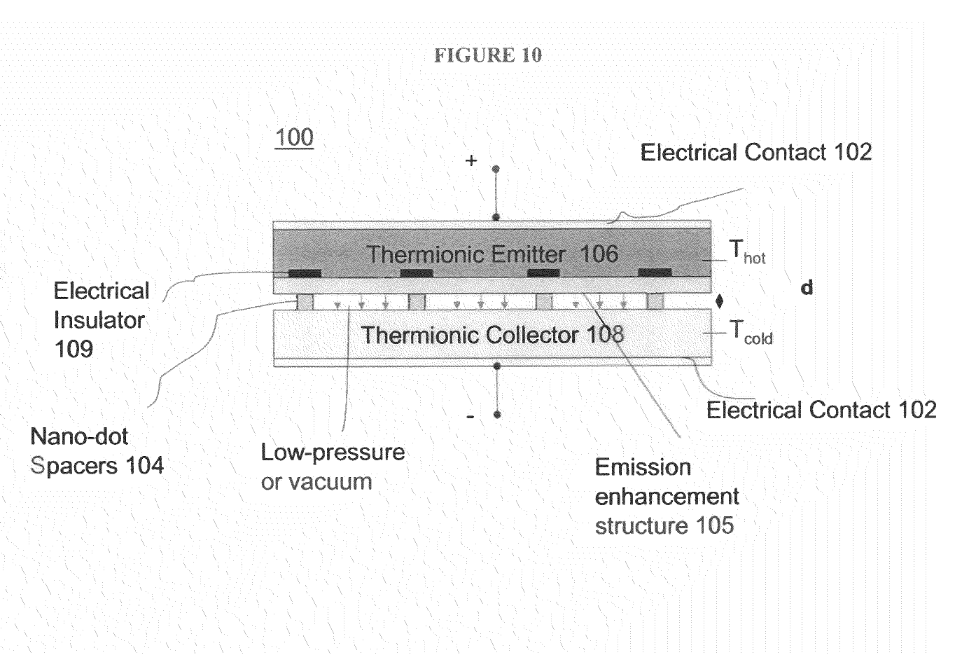

In another embodiment of the invention, self-assembled nano-dots (SAND) and/or non-self-assembled nano-dots (NSAND) form spacers in thermo photovoltaic devices. In these devices, the small gap separation permits where the evanescent infra-red blackbody radiation waves from a hot-body to be “optically” coupled to a p-n junction's emitter surface of another body across the gap. FIG. 9 shows a thermo-photovoltaic device 90, according to one embodiment of the invention, which benefits from the localized spacers described herein (e.g., the SAND and/or NSAND spacers). Substrates 96 and 98 are separated by localized spacers 94 shown illustratively in FIG. 9 as nanodots. In one embodiment, an electrical insulator 99 is used to prevent “shorting” of the upper and lower substrates. In a thermo-photovoltaic device, according to one embodiment of the invention, blackbody photons in substrate 96 tunnel and create electron-hole pairs in a p-n junction in substrate 98. Electrical contacts 92 to the top and backside of substrate 98 collect the photovoltaic-generated voltage and current. P-N junction, part of 98, in one embodiment of the invention could be in Si or Ge or GaₓIn₁₋ₓAs junction or GaₓIn₁₋ₓAs_{y}P_{1-y} where appropriate doping defines the p and n regions. These p-n junctions could be on typical substrates like Si, Ge or GaAS or InP. The substrate separation d on the nanometer scale leads to efficient heat-to-electric conversion using tunneling-aided photons across the gap of d. Photons whose wavelength (λₑ) greater than or comparable to d will tunnel.

In this way, the thermo-photovoltaic device 90 potentially couples photons over and above the blackbody spectrum emitted by the blackbody, which in turn is dictated by Planck's radiation law. The coupling of photons in such a manner utilizes coupled evanescent modes to transfer heat from upper substrate 96 to the lower substrate 98. Thus, in one embodiment of the invention, Planck's radiation and the photon-tunneling improve the thermophotovoltaic conversion efficiency with the use of SAND and NSAND spacers.

The separation and electrical isolation by electrical insulator 99 allows the thermal isolation of the blackbody emitter, from the p-n junction cell, and thereby achieve two things. Firstly, the blackbody remains hotter and emits more photons as dictated by Planck's law. Secondly, the p-n junction remains colder and the leakage current of the p-n junction is kept low as it increases exponentially with temperature. The reduction of leakage current leads to higher open circuit voltage, fill-factor and conversion efficiency of the thermo-photovoltaic cell.

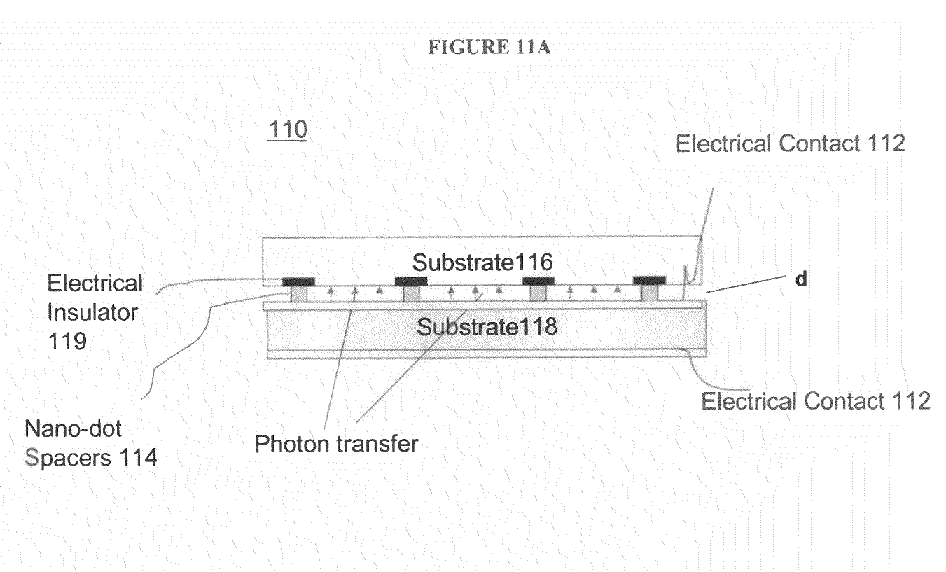

In another embodiment of the invention, self-assembled nano-dots (SAND) and/or non-self-assembled nano-dots (NSAND) form spacers for gaps to couple heat from a heat-source in one body to a hot-side of a thermionic emitter device, thereby minimizing-induced mechanical stress. FIG. 10 shows a thermionic emitter device 100, according to one embodiment of the invention, which benefits from the localized spacers described herein (e.g., the SAND and NSAND spacers). Substrates 106 and 108 are separated by localized spacers 104 shown illustratively in FIG. 10 as nanodots. In one embodiment, an electrical insulator 109 is used to preventing “shorting” of the upper and lower substrates. In a thermionic emitter device, according to one embodiment of the invention, electrons are emitted by a thermionic process using the thermal energy in the upper substrate 106 as a source of energy for thermionic emission into an evacuated space d between the upper substrate 106 and the lower substrate 108. In one embodiment of the invention, an electron emitter enhancement 105 structure (e.g., a low work function layer such as for example a cesium metal layer or a tip structure such as a conical etched structure) is provided on the gap side of upper substrate 106. The closeness of the thermionic collector (i.e., the lower substrate) to the emitter, accomplished by the SAND or NSAND structures, leads to a high efficiency of thermionic power conversion by potentially reducing space-charge effects and leading to higher electric field between emitter and collector. This enhanced electric field leads to field-enhanced thermionic or Schottky emission.

In one embodiment of the invention, the enhanced electric field emission will also be aided by the following condition where the electron wavelength (λₑ)>>d and phonon wavelength (λₚ)<<d thereby preventing phonon travel from the hot emitter to cold collector. Thus, in one embodiment of the invention, the thermal energy of the emitter is used more effectively, for causing electrons to be emitted and creating external electric power rather than dissipation by thermal conduction with phonons. In another embodiment of the invention, self-assembled nano-dots (SAND) and/or non-self-assembled nano-dots (NSAND) form spacers in the device of FIG. 10 for thermionic emitters for field-emission displays as well as thermionic energy conversion.

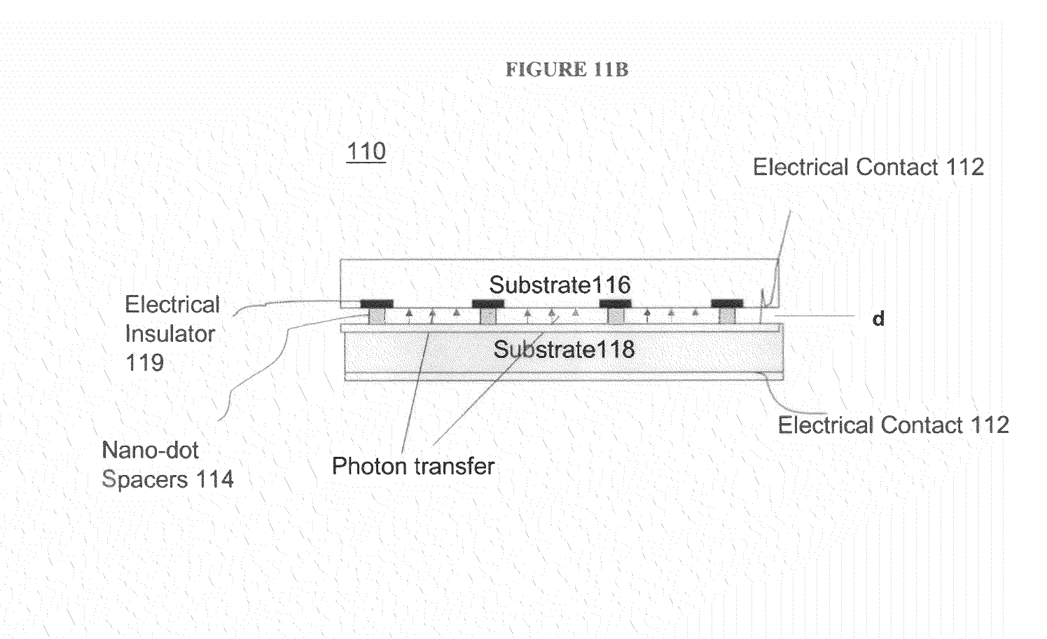

FIGS. 11A and 11B are schematic illustrations depicting devices of the invention for photonic transfer between substrates. The photonic transfer devices 110 in FIGS. 11A and 11B benefit from the localized spacers described herein (e.g., the SAND and NSAND spacers). Substrates 116 and 118 are separated by localized spacers 114 shown illustratively in FIG. 11 as nanodots. The photonic transfer device includes first and second substrates 116 and 118 separated from one another by a distance d. A plurality of localized spacers connects the first and second substrates together. In one embodiment, an electrical insulator 119 is used to preventing “shorting” of the upper and lower substrates. A sub-micron separation distance between the first and second substrates is configured to provide tunneling of photons (whose wavelengths are comparable or larger than the spacer) between the first and second substrates. As shown in FIG. 11, lower substrate 118 is an active substrate including for example a light emitting diode or a laser emitter driven by the electrical contacts 112. Light of the appropriate wavelength λₚ>>d is coupled into the upper substrate 116 and can thereafter be forwarded from upper substrate 116. Accordingly, in the device of FIG. 11A, substrate 116 includes a photon coupler 120 (e.g., an antireflection film or fiber optic attachment) coupling photons away from substrate 116 and the photonic transfer device 110. In the device of FIG. 11A, substrate 118 includes a photon generator such as a laser or a light emitting device (LED) which generates the photons, and a separation distance between the first and second substrates is configured to tunnel the photons between the first and second substrates.

In another embodiment shown in FIG. 11B, one substrate such as for example substrate 118 includes a photon emitter like an LED 122 and the other substrate 116 includes for example a photon receiver 124 such as a waveguide or a photodetector. The close proximity of the substrates 116 and 118 facilitated by the SAND or NSAND structures discussed above would be useful in integrated optics and complex optical circuits or optical communication or perhaps even in optical computers. While shown in FIG. 11B with photons being coupled to the upper substrates, regions of the upper and lower substrates could contain either photon emitters or waveguide sections or photodetectors such that optical communication would be bi-directional.

Numerous modifications and variations of the invention are possible in light of the above teachings. It is therefore to be understood that within the scope of the appended claims, the invention may be practiced otherwise than as specifically described herein.

1. An electronic transfer device structure comprising:
first and second substrates separated from one another;
a plurality of localized spacers connecting the first and second substrates together;
at least one of the localized spacers having a lateral dimension less than 350 nm; and
a sub-micron separation distance between the first and second substrates configured to tunnel carriers between the first and second substrates.

2. The device of claim 1, wherein the plurality of localized spacers comprises a plurality of a self-assembled nano-dots formed on a surface of either the first or second substrate.

3. The device of claim 2, wherein the self-assembled nano-dots have a lateral or a height dimension in the range of 1 to 50 nm.

4. The device of claim 1, wherein the plurality of localized spacers comprise an assembled structure of nano-dots formed and patterned on the surface of either the first or second substrate, and
the nano-dots have a lateral or a height dimension in the range of 1 to 50 nm.

5. The device of claim 2, wherein the nanodots comprise a density of less than 10¹⁰ nanodots/cm⁻².

6. The device of claim 2, wherein the nanodots comprise a density of less than 10⁸ nanodots/cm⁻².

7. The device of claim 2, wherein the nanodots comprise at least one of Ge, GaN, InAs, InGasAs, Si, iron silicide, Sn, In, InSn, AgSn, Bi, and Sb nanodots formed on the first or second substrate.

8. The device of claim 1, wherein at least one of the first and second substrates comprise organic semiconductor substrates.

9. The device of claim 1, further comprising:
an electrically insulator disposed at a position on at least one of the first and second substrates adjoining the localized spacer.

10. The device of claim 1, wherein at least one of the first and second substrates comprise materials for at least one of an integrated circuit device package, a heat sinking device, a thermo photovoltaic device, a thermionic device, and a thermo-tunneling device.

11. A heat transfer device structure comprising:
first and second substrates separated from one another;
a plurality of localized spacers connecting the first and second substrates together;
at least one of the localized spacers having a lateral dimension less than 350 nm; and
a sub-micron separation distance between the first and second substrates configured to provide heat transfer between the first and second substrates.

12. The device of claim 11, wherein the localized spacer comprises a plurality of nano-dots formed on a surface of either the first or second substrate.

13. The device of claim 12, wherein the self-assembled nano-dots have a lateral or a height dimension in the range of 1 to 50 nm.

14. The device of claim 11, wherein the plurality of localized spacers comprise an assembled structure of nano-dots formed and patterned on the surface of either the first or second substrate, and
the nano-dots have a lateral or a height dimension in the range of 1 to 50 nm.

15. The device of claim 12, wherein the nanodots comprise a density of less than 10¹⁰ nanodots/cm⁻².

16. The device of claim 12, wherein the nanodots comprise a density of less than 10⁸ nanodots/cm⁻².

17. The device of claim 12, wherein the nanodots comprise at least one of one of Ge, GaN, InAs, InGasAs, Si, iron silicide, Sn, In, InSn, AgSn, Bi, and Sb nanodots formed on the first or second substrate.

18. The device of claim 11, wherein at least one of the first and second substrates comprise organic semiconductor substrates.

19. The device of claim 11, further comprising:
an electrically insulator disposed at a position on at least one of the first and second substrates adjoining the localized spacer.

20. The device of claim 11, wherein at least one of the first and second substrates comprise materials for at least one of an integrated circuit device package, a heat sinking device, a thermo photovoltaic device, a thermionic device, and a thermo-tunneling device.

21. An integrated circuit device package comprising:
first and second substrates separated from one another;
a plurality of localized spacers connecting the first and second substrates together;
at least one of the localized spacers having a lateral dimension less than 350 nm; and
said first substrate including integrated circuitry, and
a sub-micron separation distance between the first and second substrates configured to provide heat transfer between the first and second substrates in order to cool the integrated circuitry of the first substrate.

22. The package of claim 21, wherein the first substrate comprises a semiconductor substrate and the second substrate comprises a heat sink.

23. The package of claim 22, wherein the heat sink comprises a copper heat sink.

24. A thermo-photovoltaic device comprising:
first and second substrates separated from one another;
a plurality of localized spacers connecting the first and second substrates together;
at least one of the localized spacers having a lateral dimension less than 350 nm; and
a sub-micron separation distance between the first and second substrates configured to provide radiation transfer between the first and second substrates;
said first substrate comprising a p-n junction; and
said second substrate comprising a radiator radiating the p-n junction.

25. A thermionic emitter device comprising:
first and second substrates separated from one another;
a plurality of localized spacers connecting the first and second substrates together;
at least one of the localized spacers having a lateral dimension less than 350 nm; and
said first substrate comprising a thermionic emitter disposed on a side of the first substrate adjacent the second substrate;
a collector disposed on a side of the second substrate adjacent the first substrate and
a sub-micron separation distance between the first and second substrates configured to provide electron tunneling between the thermionic emitter and the collector.

26. A thermo-tunneling device comprising:
first and second substrates separated from one another;
a plurality of localized spacers connecting the first and second substrates together;
at least one of the localized spacers having a lateral dimension less than 350 nm; and
a sub-micron separation distance between the first and second substrates configured to provide electron tunneling between the first and second substrates; and
said first substrate comprising an electron tunneling receptor; and
said second substrate comprising an electron tunneling donator.

27. A photonic transfer device comprising:
first and second substrates separated from one another;
a plurality of localized spacers connecting the first and second substrates together;
at least one of the localized spacers having a lateral dimension less than 350 nm;
said first substrate comprising a photon coupler coupling photons away from the first substrate;
said second substrate comprising a photon generator which generates said photons; and
a sub-micron separation distance between the first and second substrates configured to tunnel said photons between the first and second substrates, wherein wavelengths of the photons tunneled are comparable or larger than the separation distance.

28. A substrate-to-substrate coupling structure comprising:
a first substrate and a second substrates separated from the first substrate by a sub-micron distance configured to couple electrical carriers or heat between one of the first and second substrates to the other;
a plurality of self-assembled nanodots connecting the first and second substrates together; and
said nanodots formed by growth of a material of the nanodot on the first substrate.

29. The structure of claim 28, wherein the plurality of self-assembled nano dots comprises a set of nanodots remaining on the first substrate after etch removal of selected ones of the nanodots initially formed on the first substrate.

30. A charge transfer method comprising:
providing charge carriers to a first substrate separated from a second substrate by at least one localized spacer having a lateral dimension less than 350 nm; and
tunneling the charge carriers from the first substrate to the second substrate across a sub-micron gap between the first and second substrates formed by the at least one localized spacer.

31. A method for transferring heat between substrates, comprising:
providing heat to a first substrate separated from a second substrate by at least one localized spacer having a lateral dimension less than 350 nm; and
coupling the heat from the first substrate to the second substrate across a sub-micron gap of between the first and second substrates formed by the at least one localized spacer.
